(19) United States
(12) Patent Application Publication
(10) Pub. No.: US 2025/0272889 A1
(43) Pub. Date: Aug. 28, 2025

(54) DEEP LEARNING BASED IMAGE RECONSTRUCTION

(71) Applicant: The General Hospital Corporation, Boston, MA (US)

(72) Inventors: Bin Deng, Charlestown, MA (US); Stefan A. Carp, Charlestown, MA (US)

(21) Appl. No.: 18/858,643

(22) PCT Filed: Apr. 20, 2023
(86) PCT No.: PCT/US2023/066000

§ 371 Date: Oct. 21, 2024

Related U.S. Application Data
(60) Provisional application No. 63/332,920, filed on Apr. 20, 2022.

(51) Int. Cl. G06T 11/00; G06T 5/60

(52) U.S. Cl. CPC G06T 11/006; G06T 5/60; G06T 2207/10101; G06T 2207/10116; G06T 2207/20081; G06T 2211/441

(57) ABSTRACT

An image may be reconstructed from sensor data, which may include optical imaging data such as diffusion optical tomography (“DOT”) data. The sensor data are received by a computer system. A machine learning model is accessed with the computer system, where the machine learning model includes a first subnetwork that receives sensor data as an input and generates an intermediate image as a first output, and a second subnetwork that receives the first output from the first subnetwork and generates an enhanced image as a second output. The sensor data are input to the machine learning model using the computer system, generating an enhanced image as an output. The enhanced image may have higher spatial resolution, reduced noise, or other improved image quality. Structural images may be passed as an additional input to the second subnetwork of the machine learning model to increase the spatial resolution of the enhanced image.

### CROSS-REFERENCE TO RELATED APPLICATIONS

This application claims the benefit of U.S. Provisional Patent Application Ser. No. 63/332,920, filed on Apr. 20, 2022, and entitled “DEEP LEARNING BASED MULTIMODAL TOMOGRAPHIC IMAGE RECONSTRUCTION,” which is herein incorporated by reference in its entirety.

### STATEMENT OF FEDERALLY SPONSORED RESEARCH

This invention was made with government support under CA187595 and EB027726 awarded by the National Institutes of Health. The government has certain rights in the invention.

### BACKGROUND

Functional imaging modalities, such as positron emission mammography (“PEM”), contrast-enhanced mammography (“CEM”), contrast-enhanced ultrasound (“CEUS”), and various magnetic resonance imaging (“MRI”)-based techniques have been explored and shown promise to improve specificity of breast cancer detection and diagnosis. However, the cost, availability, and/or the need of intravenous injection of radioactive tracers, contrast agents, or microbubbles limits the broad clinical adoption of these technologies. In this context, near-infrared (“NIR”) diffuse optical tomography (“DOT”) has emerged as a potential solution as a cost-effective, safe, and noninvasive tool for functional imaging of breast cancer.

Using non-ionizing NIR light, DOT can capture abnormal deep tissue neovasculature and metabolism through quantitative in vivo tomographic images of total hemoglobin concentration [HbT] and tissue oxygenation (SO₂). Malignant tumors appear on DOT images with elevated HbT and altered SO₂, driven by hallmarks of cancer such as angiogenesis and accelerated metabolism that occur as soon as tumors reach 1-2 mm³.

Despite the evident sensitivity to cancer pathophysiology, the clinical utility of DOT for diagnosis is hindered by two factors.

First, at the limited spatial resolution of approximately 1 cm level, DOT can struggle in characterizing smaller lesions (e.g., ≤1 cm), which constitute approximately 40% of all lesions seen in the diagnostic setting. The loss of spatial resolution and contrast recovery is an unfortunate byproduct of the regularization typically required to ensure convergence in solving the ill-posed DOT inverse problem. Efforts in utilizing more sophisticated reconstruction methods with sparse regularization and compressed sensing have been attempted, but only achieved incremental improvement in image quality.

Second, the reconstruction algorithms for DOT are built upon iterative optimization with a finite-element (“FEM”) numerical model of light transport. This is a complex process that often involves expert knowledge of DOT to optimize the reconstruction performance for each individual case, posing a technical obstacle for translating DOT as a clinical tool. Further, required preprocessing steps (e.g., meshing, data pruning, etc.), in addition to iterative optimization render the current DOT image reconstruction pipeline labor-intensive and time-consuming (typically hours per patient), posing a logistical challenge for timely decision-making by radiologists in the clinic.

A new approach capable of rapidly recovering high-resolution, accurate images for all lesions with minimal human intervention would be advantageous to translate the benefits of functional DOT in the diagnostic setting.

### SUMMARY OF THE DISCLOSURE

In one aspect of the present disclosure, a method for reconstructing an image from sensor data is provided. The method includes receiving, by a computer system, sensor data from an imaging system. A machine learning model is also accessed with the computer system, where the machine learning model includes a first subnetwork that receives sensor data as an input and generates a first output as an intermediate image, and a second subnetwork that receives the first output from the first subnetwork and generates a second output as an enhanced image. The sensor data are input to the machine learning model using the computer system, generating an enhanced image as an output. The enhanced image may be presented to a user with the computer system.

In another aspect of the present disclosure, a method for training a machine learning model for multimodal image reconstruction is provided. The method includes accessing first imaging data with a computer system, where the first imaging data were acquired from a group of subjects. Second imaging data are also accessed with the computer system, where the second imaging data were also acquired from the group of subjects and have a higher spatial resolution than the first imaging data. The first imaging data are assembled into a first training dataset, and the second imaging data are assembled into a second training data set. A machine learning model is accessed with the computer system, where the machine learning model includes a first subnetwork that receives first imaging data as an input and generates an intermediate image as a first output, and a second subnetwork that receives the first output from the first subnetwork and generates an enhanced image as a second output. The first subnetwork is trained on the first training dataset, and the second subnetwork is trained on the second training data set. The trained first subnetwork and the trained second subnetwork may then be stored as a trained machine learning model.

### BRIEF DESCRIPTION OF THE DRAWINGS

FIG. 1 illustrates an example machine learning model for tomographic image reconstruction, which includes a first subnetwork having a first component (e.g., a fully connected layer component) and a second component (e.g., an autoencoder component) and a second subnetwork having a third component (e.g., a convolutional neural network component).

FIG. 2 illustrates an example workflow for a two-step training of a machine learning model such as the one illustrated in FIG. 1.

FIG. 3 illustrates an example phantom geometry with an 8-mm diameter inclusion embedded within a breast-shaped boundary represented by cloud points of dual-resolution mesh nodes. Sources and detectors are plotted as overlays on the top and bottom of the phantom, respectively.

FIG. 4 illustrates an example learning-based noise model using a generative adversarial network (“GAN”) trained on real measurements on phantoms, which may be used to generate sensor data to which realistic noise has been added (e.g., optical imaging data or other functional imaging data to which realistic noise has been added).

FIG. 5 is a flowchart setting forth the steps of an example method for reconstructing an image from sensor data (e.g., optical imaging data) and/or enhancing the quality of a reconstructed image based on structural imaging data (e.g., x-ray imaging data).

FIG. 6 is a flowchart setting forth the steps of an example method for training a machine learning model in accordance with some examples described in the present disclosure.

FIG. 7 is a block diagram of an example machine learning-based image reconstruction system that can implement the methods described in the present disclosure.

FIG. 8 is a block diagram of example components that can implement the system of FIG. 7.

FIG. 9 is a block diagram of an example combined optical/digital breast tomosynthesis imaging system that may be implemented when acquiring sensor data and structural imaging data.

### DETAILED DESCRIPTION

Described here are systems and method for high-resolution, real-time tomographic optical imaging. In general, the disclosed systems and methods implement a deep learning model, or other machine learning model, to reconstruct optical images directly from measurement signals (e.g., sensor data acquired with an optical imaging system). In some examples, the deep learning model may also take co-registered anatomical images as an input for more robust model performance. Thus, in some examples, the machine learning model receives multimodal data as an input. The multimodal data may include high-resolution structural images and lower resolution functional imaging signals. As a non-limiting example, high-resolution structural images may include those acquired with x-ray imaging (e.g., x-ray digital breast tomosynthesis (“DBT”), computed tomography (“CT”), and the like), magnetic resonance imaging (“MRI”), ultrasound, and so on. The lower resolution functional imaging signals may include optical imaging signals (e.g., optical imaging signals acquired with diffuse optical tomography (“DOT”), fluorescence, or other optical imaging modalities), microwave tomography, positron emission tomography (“PET”), and so on.

More generally, the present disclosure provides an image reconstruction framework for single modality or multimodal imaging data that can be used to reconstruct images from imaging data acquired from a variety of imaging modalities, including optical imaging, such as diffuse optical tomography (“DOT”); magnetic resonance imaging (“MRI”), including T1-weighted and/or T2-weighted structural imaging, magnetic resonance elastography (“MRE”), and so on; fluorescence tomography with x-ray computed tomography (“CT”); and so on. Advantageously, when receiving multimodal imaging data as an input, the disclosed systems and methods provide an image reconstruction framework for the multimodal combination of a high-resolution structural imaging modality with a non-structure orientated imaging modality that may have unique contrast, but lower resolution than the structural imaging modality.

As will be described in more detail below, the machine learning models described in the present disclosure provide a number of improvements and advantages. As one example, by using a 3D convolutional neural network (e.g., a 3D U-Net) in the back end of the machine learning model, inclusion features in the reconstructed images can be further enhanced. Additionally, by utilizing skip connections that transfer the high-resolution information from the low-level layers of the analysis path to the high-level layers of the synthesis path, U-Nets can leverage both local and global information to enhance the image quality. This contributes to both precise localization and significant improvement in quantification accuracy.

As another example, a unique prior-weighted loss function is implemented during training to effectively characterize small perturbations at the lesion location in the optical reconstructions within a noisy background. The prior information is only used during training for loss calculation and no prior knowledge on inclusion lesion size and location is needed during the reconstruction using the trained machine learning model in deployment.

As yet another example, input layer of the machine learning model may indiscriminately take in all sensor data, including those that fall within and below the noise floor. Data pruning to get rid of noisy and invalid measurement pairs, a cumbersome preprocessing step typically needed in the FEM-based conventional methods, is an integral part of the machine learning-based image reconstruction learned directly through a strictly data-driven approach. This eliminates the need to change model structure and train separate models for different applications. A unified model can be used as long as the same configuration of the DOT imaging hardware is used.

The disclosed systems and methods provide an additional advantage by overcoming the low-resolution, low-accuracy problems encountered by currently existing interactive optical image reconstruction methods, which are time-consuming and have been limiting the clinical translation of functional optical imaging.

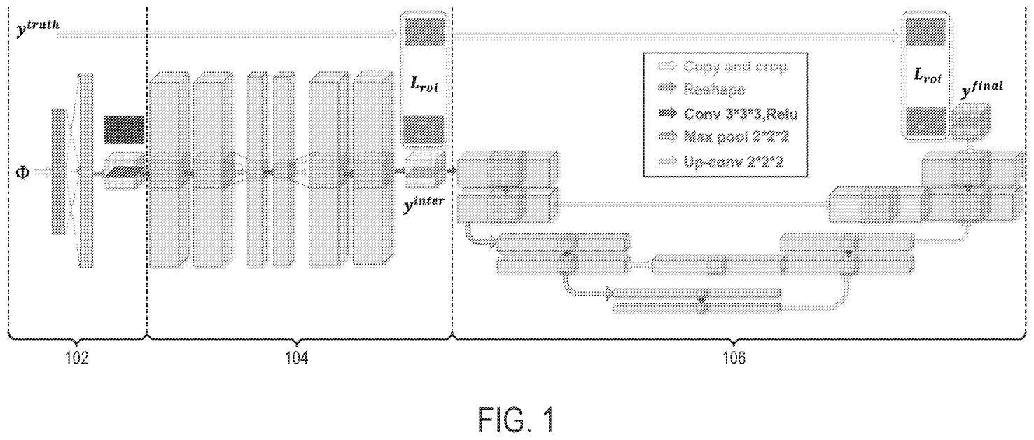

Referring now to FIG. 1, the deep learning model framework described in the present disclosure generally includes a machine learning model 100 having three components: a fully connected layer component 102, an autoencoder component 104, and a convolutional neural network component 106. The first component 102 and second component 104 may form a first subnetwork that reconstructs an intermediate image, and the third component 106 may form a second subnetwork that enhances the quality of the intermediate image, such as by improving the spatial resolution, reducing noise, or providing other image quality enhancements. In some implementations, the different components of the machine learning model 100 may be used separately, or in different combinations. For instance, the third component 106 may be used separately to enhance an already reconstructed image, or the second component 104 may be used to extract features (e.g., abnormalities such as inclusions) from an image, or the first component 102 and the second component 104 may be used to reconstruct intermediate images, or the first component 102 and the third component 106 may be used in combination such that an intermediate image may be generated by the first component 102 and passed as an input to the third component 106.

The fully connected layer component 102 receives sensor domain imaging data and approximates an inversion operator that converts the imaging data from the sensor domain to the image domain. As a non-limiting example, the fully connected layer component 102 may include two fully connected layers—an input layer and a hidden layer—activated by an activation function. The activation function may be a rectified linear unit (“ReLU”) function, a hyperbolic tangent (“tan h”) activation function, or other suitable activation function. The fully connected layer component 102 may also include a reshape operation to transfer the sensor-domain data to image-domain data. These fully connected layers function as an approximation of the inversion operator that resolves the spatial distribution of absorbers from a finite number of measurement pairs. For example, the fully connected layers may map the correlation between paired amplitude and phase sensor-domain data (e.g., DOT data, or other sensor-domain data) and approximate the projection from the sensor domain to the image domain. To enhance the robustness of the fully connected network and prevent overfitting, a dropout rate of 0.8 may be used.

The image-domain data output from the fully connected layer component 102 (i.e., the reshaped volume data) are then passed as an input to the autoencoder component 104. The autoencoder component extracts features (e.g., inclusion features), such as inclusion size, depth, location, and contrast. The autoencoder component 104 may include a 3D convolutional autoencoder network. For example, the autoencoder component 104 may include ReLU activated convolutional and deconvolutional layers similar to a winner-take-all autoencoder with 3D kernels. As noted, the autoencoder component 104 can extract features, such as high-level features with spatial sparsity representations.

The intermediate images output from the autoencoder component 104 are then passed to the convolutional neural network component 106, which can enhance features in the images (e.g., inclusion features) and reduce noise. As a non-limiting example, the convolutional neural network component 106 may include a convolutional neural network having a 3D U-Net architecture, such as a 3D U-Net with three resolution steps. Each layer in the analysis path of the convolutional neural network component 106 may include two 3×3×3 padded convolutions with ReLU activation followed by a 2×2×2 max pooling operation with strides of two in each dimension for downsampling. As an example, starting with 32 feature channels, at each downsampling step, the number of feature channels may be doubled. In the synthesis path, of the convolutional neural network component 106, each layer may include an up-convolution of 2×2×2 by strides of two followed by one 3×3×3 convolution with ReLU activation. Skip connections from layers of equal resolution in the analysis path provide the high-resolution features to the synthesis path. The final layer, a 1×1×1 convolution, is used to map the 32-channel features to the unified final image volume.

As will be described in more detail below, the machine learning model may be trained on training data that include simulated sensor-domain measurements, such as simulated DOT measurements. In some examples, scaled and realistic noise may be added to the sensor-domain data used for training data. For instance, a generative adversarial network (“GAN”) may be used to create training data with a realistic noise profile of the imaging hardware, as described below in more detail.

As a non-limiting example, the deep learning model may be referred to as a deep learning-based tomographic optical breast imaging (“DeepTOBI”) reconstruction framework. The DeepTOBI framework uses DNNs for both direct image reconstruction (e.g., the autoencoder component) and resolution improvement (e.g., the convolutional neural network component) in DOT. In some examples, the DeepTOBI framework is designed to work in synergy with a combined DBT-DOT system capable of high-speed, high-density optical imaging, such as the imaging system described in co-pending U.S. Patent Application Publication No. US 2016/0228006 and U.S. Pat. No. 9,265,460, both of which are incorporated by reference in their entirety. It is an advantage of the present disclosure that the disclosed DeepTOBI framework can provide for a DBT-DOT system with improved performance, such that it is capable of generating functional DOT images with superior image quality. Accordingly, the DeepTOBI framework can allow for a DBT-DOT system to support effective and safe downgrading of benign lesions to reduce unnecessary biopsies.

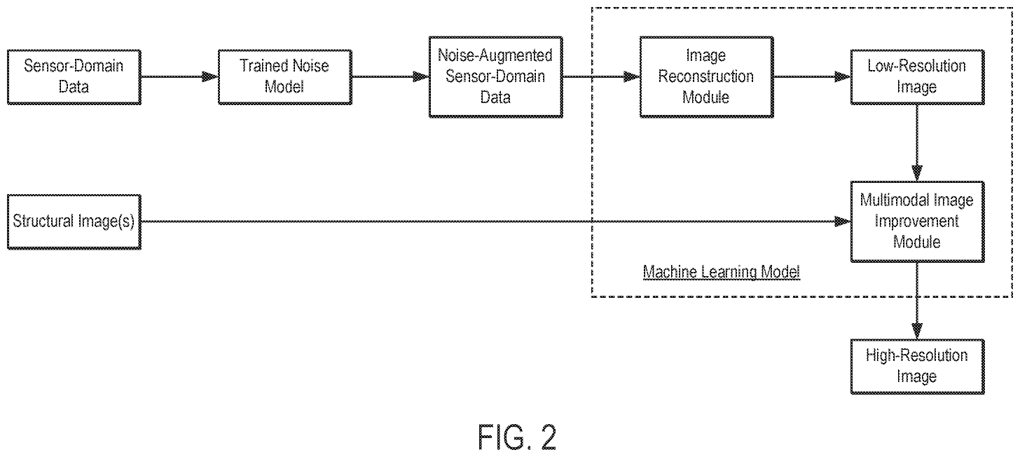

An example workflow for training a DeepTOBI machine learning model is illustrated in FIG. 2. Sensor-domain data and structural images are passed as multimodal inputs to the DeepTOBI machine learning model. The sensor-domain data and structural images may be simulated data and images, or may be acquired from a subject or group of subjects (e.g., a phantoms, human subjects, non-human subjects, and so on). In some examples, the sensor-domain data may include both amplitude and phase data (e.g., both amplitude and phase from CW and FD data) as inputs for more accurate recovery of optical properties. If simulated data ae used as training inputs, the simulated sensor-domain data are first passed as an input to a noise model (e.g., a GAN-based noise model) to add realistic noise to the data, generating noise-added sensor-domain data as an output. The image reconstruction module of the machine learning model (e.g., the fully connected layer component 102 and autoencoder component 104) may be trained on the noise-added sensor-domain data. The image reconstruction module outputs a low-resolution intermediate image, which can be used with the structural image(s) to train the multimodal image improvement module (e.g., the convolutional neural network component 106) of the machine learning model. The trained model then outputs a high-resolution image reconstructed from the sensor-domain data as an output.

As mentioned above, in some examples the machine learning model may be trained on simulated data. One challenge in adopting deep learning methods for DOT image reconstruction is the lack of ground truth knowledge of the heterogenous distribution of tissue constituents that give rise to the contrast seen in DOT images. One example approach to address this challenge is to use simulated optical measurements on digital phantoms.

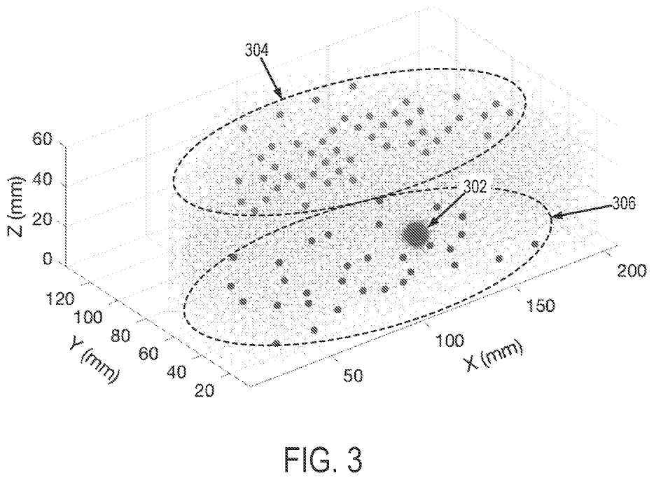

For instance, a 3D breast phantom can be positioned inside a 216×144×60 mm³ bounding volume, as shown in FIG. 3, which depicts a sample phantom geometry with an 8-mm diameter inclusion 302 embedded within a breast-shaped boundary represented by cloud points of the dual-resolution mesh nodes. Within the breast boundary, a single spherical inclusion 302 with diameters ranging from 8 to 16 mm (mean±std: 12.01+2.33 mm, uniform distribution) was inserted at random x-y locations at the central depth (z=30 mm). Based on this geometry, dual-resolution tetrahedral meshes, composed of a fine mesh (mean nodal distance of 0.36 mm) within the inclusion region and a coarse mesh (mean nodal distance of 5.92 mm) outside, was generated for each geometry.

As shown in FIG. 3, 48 continuous-wave (“CW”) sources (e.g., indicated by the dots in the region 304) and 32 detectors (e.g., indicated by the dots in the region 306), spatially distributed in the same pattern as in an example clinical multimodal DBT-DOT system, were used to generate a set of 1,536 simulated CW optical measurements at 690 nm using a diffusion equation-based forward model for each digital phantom. To this end, absorption coefficients (Ma) representative of typical tissue optical properties were randomly assigned to the inclusion (0.17±0.05 cm⁻¹) and homogenous background (0.06+0.01 cm⁻¹), respectively, in each phantom case, while reduced scattering coefficients (μ′ₛ) were fixed at 9.250 cm⁻¹ across phantoms. The diffusion equation may then be numerically solved on the dual-resolution mesh using a finite-element solver.

When using simulated data as a training input, synthetic shot and electronic noise may be added to the simulated sensor-domain data. Noise characteristics of real measurements, including those reflecting hardware non-idealities, are much more complex. To facilitate training of the machine learning model for real-world tasks, a GAN may be used to learn complex distributions to estimate realistic noise profiles from real measurements on tissue phantoms, or the like. Advantageously, using a GAN to create noise profiles that match the imaging hardware characteristics assists in robust model training.

As a non-limiting example, to ensure the simulated data resemble the signal amplitude and noise profiles of real measurements, DOT data of a phantom (e.g., a homogenous silicone rubber slab phantom, such as a phantom that is 6.5-cm thick with μₐ=0.024 cm⁻¹ and μₛ′=7.275 cm⁻¹ at 690 nm) may be collected by a multimodal optical imaging system, or other imaging system. These data may then be used to characterize the dynamic range and noise levels. A forward simulation based on the same geometry and optical properties may be performed to serve as a reference. Using the set of measured and simulated fluence at each source and detector pair, a global scaling factor, α, that brings the simulated data in the range of the experimental data may be determined as,

$$arg {min}_{α} {‖ ( α - {Φ}_{s} ( s , d ) - {Φ}_{m} ( s , d ) ‖}_{2} ; \qquad ( 1 )$$

where, S is the index of source optodes, other optical sensors, or other non-optical sensors; d is the index of detector optodes, other optical sensors, or other non-optical sensors; Φₘ(s,d) is the measured fluence data averaged over four measurements of the phantom; Φₛ(s,d) is the simulated data using the forward model described above; and ∥⋅∥₂ denotes the L2 norm.

Two types of pseudo-random noise (e.g., the signal independent electronic noise and signal dependent shot noise) may be added to the scaled forward model output using the following:

$${Φ}_{s}^{′} ( s , d ) = α \cdot {Φ}_{s} ( s , d ) + {n}_{elec} + {n}_{shot} ; \qquad ( 2 )$$

$${n}_{elec} = {σ}_{elec} \times \vert {U}_{1} \vert ; \qquad ( 3 )$$

$${n}_{shot} = {σ}_{shot} \times {U}_{{2}^{\times }} \sqrt{\vert α \cdot {Φ}_{s} ( s , d ) \vert} ; \qquad ( 4 )$$

where Φ′ₛ(s,d) is the scaled simulated data with noise added; n_{elec} and nₛₕₒₜ are electronic and shot noise, respectively; U1 and U2 are two independent random variables with the standard normal distribution; and σ_{elec} and σₛₕₒₜ are factors that control the level of added electric and shot noise, respectively, which may be determined by the following minimization process:

$$arg {min}_{{σ}_{elec} , {σ}_{shot}} {‖ {Φ}_{s}^{′} ( s , d ) - {Φ}_{m} ( s , d ) ‖}_{2} . \qquad ( 5 )$$

The scaled simulated data with added noise can accurately recapitulate the characteristics of signals collected from real measurements. The same global scaling factor α and noise factors σ_{elec} and σₛₕₒₜ may then be applied to the outputs from the forward simulation/model.

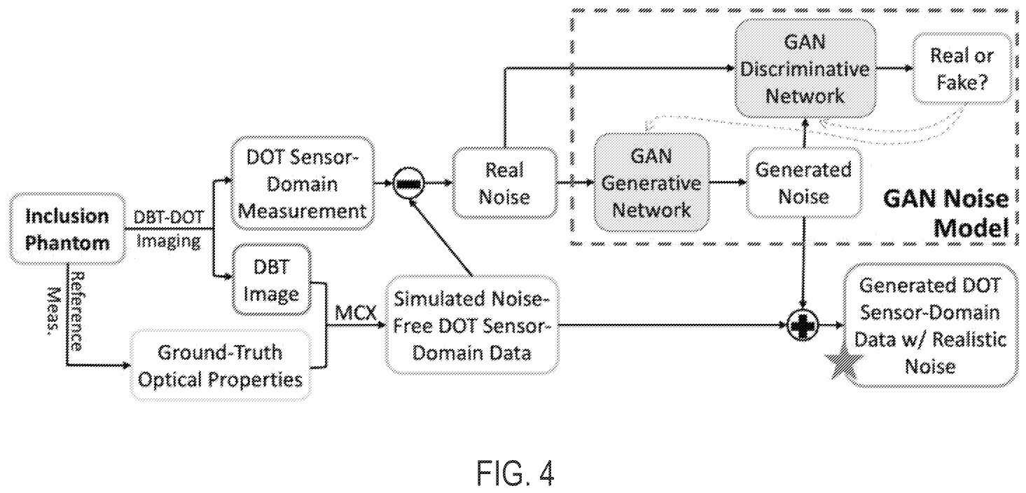

In some examples, noise modeling can be implemented using one or more GANs. For example, the learning-based noise modeling using a GAN illustrated in FIG. 4 may be trained on real measurements of phantoms for robust synthetic-to-real domain adaptation. As a non-limiting example, DBT-DOT data acquired from a phantom (e.g., a silicone inclusion phantom) may be acquired. Optical properties of the phantom may also be measured by a reference multi-wavelength frequency-domain (“FD”) NIRS system to be used as the ground truth distribution of optical properties of phantoms with different combinations of acquisition repetitions, phantom thicknesses, inclusion sizes, inclusion depths, inclusion locations, and contrast, a significant number (e.g., over 16,000) unique DBT-DOT measurements may be acquired on phantoms for training. Then, real noises (e.g., real noises quantified by mean-centered differences between calibrated real measurements and simulated DOT data) may be used as inputs to train a GAN. To facilitate stability of training, a DCGAN architecture may be used. The generative network may be constructed with deconvolutional (deconv) blocks including deconvolution, batch normalization (BN), and rectified linear unit (ReLU) layers. The discriminator network may be constructed with convolutional (conv) blocks including convolutional, BN, and leaky ReLU layers. Additionally or alternatively, a Wasserstein GAN with gradient penalty (“WGAN-GP”) objective function may be adopted to facilitate training convergence. Once trained, the GAN may generate realistic noises, which may be added to simulated sensor-domain DOT data to create a DeepTOBI training dataset with both realistic breast geometry and noise profile.

Forward output data with added noise may be rescaled by min-max normalization using the minimum and maximum values across simulated data from all phantoms. All data points of each simulation, including the ones below the noise floor that may otherwise be excluded in conventional DOT image reconstruction methods, may be included as inputs to train the machine learning models. To decrease the number of parameters that need to be trained, and thus in turn reduce the computational cost, the original image volume may be downsampled (e.g., by 3×3×5) to form a ground truth 3D volume (e.g., with an x-y in-plane resolution of 3 mm by 3 mm and z resolution of 5 mm, using the downsampling of 3×3×5). The min-max normalization may also be applied to the ground truth images (e.g., ground truth optical images of μₐ at 690 nm, as a non-limiting example) to boost the rate of convergence. Minimum and maximum values used to normalize the inputs and outputs of the machine learning model may be logged and used later to preprocess the testing dataset and to restore model outputs back to meaningful values of absorption coefficients, respectively.

In the example phantom described above, because the embedded single spherical inclusion constitutes only a very small fraction (e.g., 0.14-1.15%) of the entire 3D image volume and the μₐ contrast between inclusion (or other abnormalities) and background (inclusion-to-background ratio R=2.73±0.87) is rather small, an L2 loss function may not be effective in recovering such small perturbations. Alternatively, a loss function that penalizes more heavily on inaccuracies within the abnormality-containing region-of-interest (“ROI”) may be used. As an example, a loss function that takes advantage of the prior knowledge of the location and size of the abnormalities (e.g., inclusion(s)) to impose different weights towards the L2 loss within and outside the abnormality-containing ROI may be used, such as:

$${L}_{roi} = {ω}_{roi} * {‖ {y}_{roi}^{output} - {y}_{roi}^{truth} ‖}_{2}^{2} + ( 1 - {ω}_{roi} ) * {‖ {y}_{bg}^{output} - {y}_{bg}^{truth} ‖}_{2}^{2} ; \qquad ( 6 )$$

where Lᵣₒᵢ is the prior-weighed loss function; yₜᵣᵤₜₕ and yₒᵤₜₚᵤₜ are the ground truth optical image and model output with subscripts “roi” and “bg” denoting the values within the abnormality-containing ROI and background image volume, respectively; ωᵣₒᵢ and (1−ωᵣₒᵢ) are the weights imposed to the L2 loss within and outside the abnormality-containing ROI, respectively. By setting the value of ωᵣₒᵢ between 0.5 and 1, the strength in reinforcing accuracy can be controlled within the inclusion(s) or other abnormalities.

The ωᵣₒᵢ setting may be determined by trial and error. As a non-limiting example, values that may be used in a fully trained model include ωᵣₒᵢ=0.985 and 0.9, respectively, for the intermediate and final training steps, which are close to the volume fraction of background. During training, using the prior-weighted loss function as defined in Equation (6) was observed to accelerate the learning process and improve the accuracy of inclusion, or other abnormality, location recovery using the input data that reveal no explicit information on system configuration. Also, note that the prior-weighed loss is only relevant during training; once trained, no prior knowledge is used to recover the optical images in the testing dataset using the machine learning model.

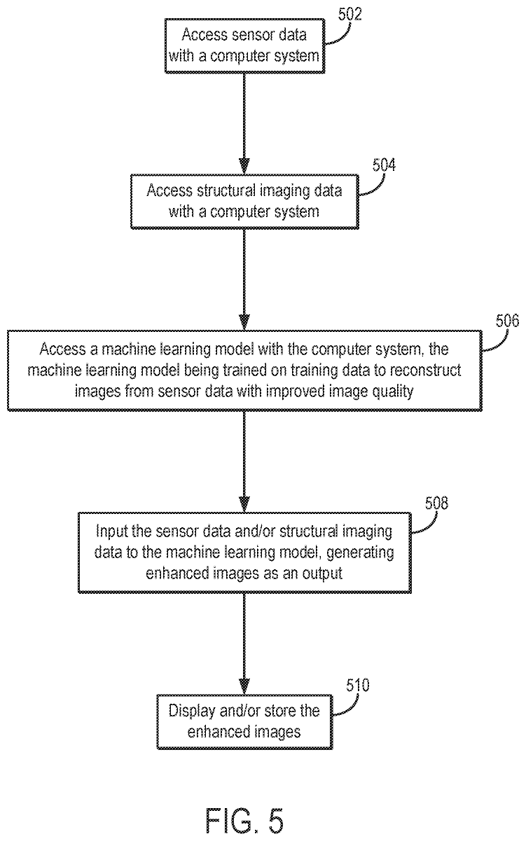

Referring now to FIG. 5, a flowchart is illustrated as setting forth the steps of an example method for generating high-resolution images from sensor data, such as optical imaging data or other functional imaging data, using a suitably trained machine learning model. As described above, the machine learning model takes sensor data as input data and generates reconstructed images as an output. For instance, optical images may be directly reconstructed from DOT measurements. Additionally, the machine learning model may also take structural (e.g., anatomical) imaging data or other higher resolution imaging data as an additional input.

The method includes accessing sensor data with a computer system, as indicated at step 502. Accessing the sensor data may include retrieving such data from a memory or other suitable data storage device or medium. Additionally or alternatively, accessing the sensor data may include acquiring such data with an imaging system and transferring or otherwise communicating the data to the computer system, which may be a part of the imaging system. As described above, in some examples the sensor data may include optical imaging data, such as DOT measurement data, which may include 3D DOT measurement data. In other examples, the sensor data may be functional imaging data acquired using other imaging modalities, such as other optical imaging modalities (e.g., fluorescence imaging), PET or other nuclear medicine imaging modalities, MRI, CT, ultrasound, and so on.

In some examples, structural imaging data may also be accessed with the computer system, as indicated at step 504. Accessing the structural imaging data may include retrieving such data from a memory or other suitable data storage device or medium. Additionally or alternatively, accessing the structural imaging data may include acquiring such data with an imaging system and transferring or otherwise communicating the data to the computer system, which may be a part of the imaging system. As described above, in some examples the structural imaging data may include x-ray images, such as DBT images. In other examples, the structural imaging data may include images data acquired with other imaging modalities, such as MRI, CT, ultrasound, or the like. In some examples, the sensor data and structural imaging data may be acquired using a single imaging system, such as a combined DOT-DBT imaging system.

More generally, the sensor data accessed in step 502 may be a first set of imaging data acquired with a first imaging modality, and the structural imaging data accessed in step 504 may be a second set of imaging data acquired with a second imaging modality, where the second imaging data have a higher spatial resolution than the first imaging data. In some examples, the first and second imaging modalities may be different imaging modalities. For instance, as described above the first imaging modality may be a functional imaging modality and the second imaging modality may be a structural imaging modality. In some other examples, the first and second imaging modalities may be the same imaging modality, but the first and second imaging data may be acquired with different acquisition techniques. For instance, the first and second imaging data may both be MRI data, but the first imaging data may include functional MRI data and the second imaging data may include structural MRI data (e.g., T1-weighted anatomical images, T2-weighted anatomical images, or the like). As another example, the first and second imaging data may be acquired with the same imaging modality, but at different spatial resolutions.

A trained machine learning model is then accessed with the computer system, as indicated at step 506. In general, the machine learning model is trained, or has been trained, on training data in order to reconstruct high-resolution images with reduced noise from sensor data. Accessing the trained machine learning model may include accessing network parameters (e.g., weights, biases, or both) that have been optimized or otherwise estimated by training the machine learning model on training data. In some instances, retrieving the machine learning model can also include retrieving, constructing, or otherwise accessing the particular model architecture to be implemented. For instance, data pertaining to the layers in the model architecture (e.g., number of layers, type of layers, ordering of layers, connections between layers, hyperparameters for layers) may be retrieved, selected, constructed, or otherwise accessed.

As described above, the machine learning model may include a three-component model having a fully connected layer component, an autoencoder component, and a convolutional neural network component. In general, an artificial neural network (e.g., a convolutional neural network or a neural network implementing an autoencoder) generally includes an input layer, one or more hidden layers (or nodes), and an output layer. Typically, the input layer includes as many nodes as inputs provided to the artificial neural network. The number (and the type) of inputs provided to the artificial neural network may vary based on the particular task for the artificial neural network.

The input layer connects to one or more hidden layers. The number of hidden layers varies and may depend on the particular task for the artificial neural network. Additionally, each hidden layer may have a different number of nodes and may be connected to the next layer differently. For example, each node of the input layer may be connected to each node of the first hidden layer. The connection between each node of the input layer and each node of the first hidden layer may be assigned a weight parameter. Additionally, each node of the neural network may also be assigned a bias value. In some configurations, each node of the first hidden layer may not be connected to each node of the second hidden layer. That is, there may be some nodes of the first hidden layer that are not connected to all of the nodes of the second hidden layer. The connections between the nodes of the first hidden layers and the second hidden layers are each assigned different weight parameters. Each node of the hidden layer is generally associated with an activation function. The activation function defines how the hidden layer is to process the input received from the input layer or from a previous input or hidden layer. These activation functions may vary and be based on the type of task associated with the artificial neural network and also on the specific type of hidden layer implemented.

Each hidden layer may perform a different function. For example, some hidden layers can be convolutional hidden layers which can, in some instances, reduce the dimensionality of the inputs. Other hidden layers can perform statistical functions such as max pooling, which may reduce a group of inputs to the maximum value; an averaging layer; batch normalization; and other such functions. In some of the hidden layers each node is connected to each node of the next hidden layer, which may be referred to then as dense layers. Some neural networks including more than, for example, three hidden layers may be considered deep neural networks.

The last hidden layer in the artificial neural network is connected to the output layer. Similar to the input layer, the output layer typically has the same number of nodes as the possible outputs. In the example machine learning models described in the present disclosure, the autoencoder component may have an output layer that outputs one or more intermediate images, and the convolutional neural network component may have an output layer that outputs one or more enhanced images (e.g., images with higher resolution, reduced noise, other improved image quality, or combinations thereof).

The sensor data and/or structural imaging data (e.g., the first and/or second imaging data) are then input to the machine learning model, generating output as enhanced images, as indicated at step 508. The sensor data (or first imaging data) are input to the first component of the machine learning model; that is, the fully connected layer component 102. The output of the fully connected layer component is passed as an input to the second component of the machine learning model; that is, the autoencoder component 104. The output of the autoencoder component (e.g., one or more intermediate images) is passed as an input to the third component of the machine learning model; that is, the convolutional neural network component 106. When structural imaging data (e.g., second imaging data) are available as an additional input, the structural imaging data (or second imaging data) may be passed as an additional input to the second component of the machine learning model, the third component of the machine learning model, or both. Additionally or alternatively, the structural imaging data (or second imaging data) may be input to a transfer-GAN that transfer learns the low-to-high-resolution transformation from the structural images (or other images in the second imaging data) instead of directly involving them in the image improvement network (i.e., the third component of the machine learning model). This low-to-high-resolution transformation may alternatively be applied to the intermediate (or enhanced) images to increase their spatial resolution.

The one or more enhanced images are output from the third component of the machine learning model. The enhanced image(s) correspond to images reconstructed from the sensor-domain data, but with higher image resolution and otherwise improved image quality (e.g., reduced noise) relative to the intermediate images and/or conventional reconstructions of the sensor data (or first imaging data). The enhanced images may include 2D images reconstructed from 2D sensor-domain data, 3D images reconstructed from 3D sensor-domain data, 2D images reconstructed from 3D sensor-domain data, and other such combinations.

The enhanced image generated by inputting the sensor data and/or structural imaging data to the trained machine learning model can then be displayed to a user, stored for later use or further processing, or both, as indicated at step 510. For instance, the images may be stored and processed by the computer system, or another computer system, to detect cancerous tissues in the images, to monitor the response of a tumor to chemotherapy or other therapy, and so on. As an example, the images may be processed to determine DOT-derived imaging markers that can be analyzed to assist a clinician in differentiating malignant and benign lesions based on their pathophysiological features.

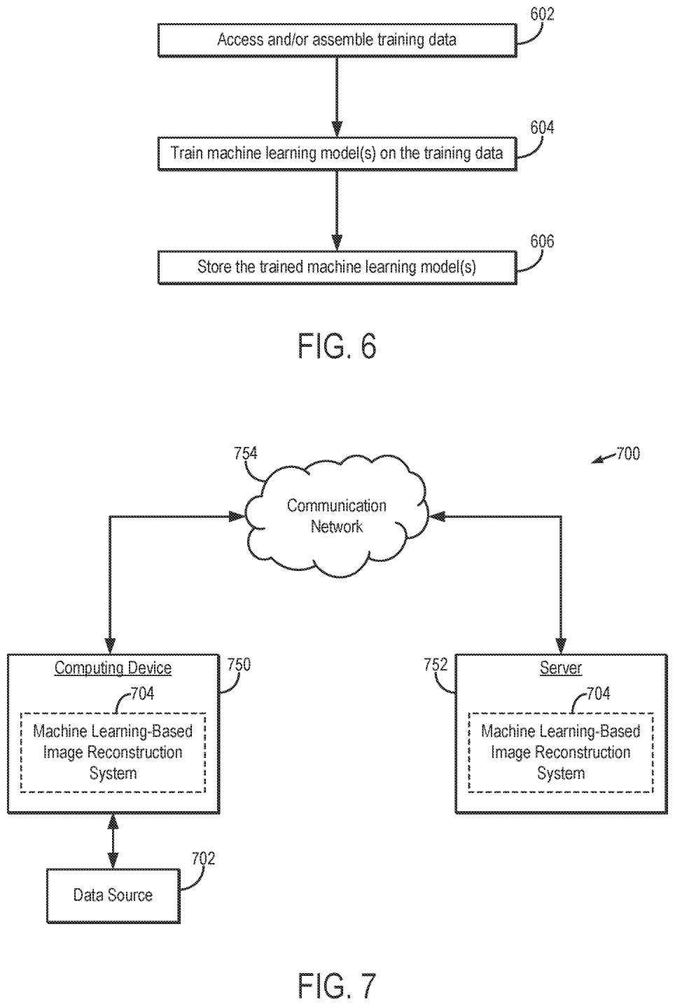

Referring now to FIG. 6, a flowchart is illustrated as setting forth the steps of an example method for training one or more machine learning models on training data, such that the one or more machine learning models are trained to receive sensor data and/or structural imaging data as input data in order to generate enhanced images as output data, where the enhanced images have increased spatial resolution, reduced noise, and/or other improved image quality relative to images reconstructed from the sensor data using conventional reconstruction techniques.

In general, the machine learning model(s) can implement any number of different model architectures. As described above, the machine learning model may be a three-component model. The first component can be a neural network that is constructed to convert sensor-domain data to image-domain data. As an example, the first component may be a fully connected layer component as described above. The second component can be a neural network that is constructed to extract features from image data and to generate intermediate images. As an example, the second component may be an autoencoder network, as described above. The third component can be a neural network that is constructed to improve the quality of, or otherwise enhance, the intermediate images. As an example, the third component may be a convolutional neural network, as described above.

The method includes accessing training data with a computer system, as indicated at step 602. Accessing the training data may include retrieving such data from a memory or other suitable data storage device or medium. Alternatively, accessing the training data may include acquiring such data with one or more imaging systems and transferring or otherwise communicating the data to the computer system. In general, the training data can include sensor data and structural images.

The method can include assembling training data from sensor data and/or structural imaging data using a computer system. This step may include assembling the sensor data and/or structural imaging data into an appropriate data structure on which the machine learning model can be trained. Assembling the training data may include generating noise-added sensor data, as described above. For example, sensor data can be accessed with the computer system and passed as an input to a noise model to inject realistic noise into the sensor data. The noise model may be, for example, a GAN-based noise model, such as those described above.

As a non-limiting example, the training data may include sensor data as a large number (e.g., 12,000) of simulated amplitude and phase DOT data. In some examples, the DOT data may be calibrated against a homogenous calibration phantom and then normalized and used as inputs in training the first and second components of the machine learning model. Ground truth distributions of absorption coefficient (μₐ) of breast models may be sampled to a volume with isotropic resolution (e.g., 1 mm³ voxels) that is large enough for most breasts, and used as the ground truth in training the machine learning model. Structural imaging data may include DBT images processed to the same field-of-view and resolution as the sensor data and used as inputs in training the third component of the machine learning model. Voxels of the standardized image volume that are beyond the breast coverage may be assigned as air on DOT and zero grayscale on DBT images.

One or more machine learning models are trained on the training data, as indicated at step 604. In general, the machine learning model can be trained by optimizing network parameters (e.g., weights, biases, or both) based on minimizing a loss function. As one non-limiting example, the loss function may be a mean squared error loss function.

Training a neural network may include initializing the neural network, such as by computing, estimating, or otherwise selecting initial network parameters (e.g., weights, biases, or both). During training, an artificial neural network receives the inputs for a training example and generates an output using the bias for each node, and the connections between each node and the corresponding weights. For instance, training data can be input to the initialized neural network, generating output data, which for the autoencoder component may be intermediate images and for the convolutional neural network component may be enhanced images. The artificial neural network then compares the generated output with the actual output of the training example in order to evaluate the quality of the output data. For instance, the output data can be passed to a loss function to compute an error. As described above, the loss function may include a prior-weighted loss function.

The current neural network can then be updated based on the calculated error (e.g., using backpropagation methods based on the calculated error). For instance, the current neural network can be updated by updating the network parameters (e.g., weights, biases, or both) in order to minimize the loss according to the loss function. The training continues until a training condition is met. The training condition may correspond to, for example, a predetermined number of training examples being used, a minimum accuracy threshold being reached during training and validation, a predetermined number of validation iterations being completed, and the like. When the training condition has been met (e.g., by determining whether an error threshold or other stopping criterion has been satisfied), the current neural network and its associated network parameters represent the trained neural network. Different types of training processes can be used to adjust the bias values and the weights of the node connections based on the training examples. The training processes may include, for example, gradient descent, Newton's method, conjugate gradient, quasi-Newton, Levenberg-Marquardt, among others.

In an example training process, the training data may be randomly split into training and validation datasets at a 4:1 ratio. During training, Adam optimizer can be used as the optimizer and k-fold cross validation can be used to minimize the loss. Hyperparameter tuning on batch size, learning rate, Adam's hyperparameters, number of hidden layers, etc., may be done using Bayesian optimization. The two-part machine learning model can be trained separately. When training the first part (i.e., the first and second components 102, 104), a modified L2 loss that penalizes heavily on inaccuracies within the inclusion ROI (e.g., the prior-weighted loss function in Eqn. (6)) may be used to enhance the recovery of inclusion-to-background contrast. The weight, ωᵣₒᵢ, can be determined empirically and may be expected to be close to the volume fraction of the background. For the training of the second part (i.e., the third component 106), an L1 loss can be used because it has strong performance in both training robustness and sharper image results for tasks related to clinical evaluation.

In an example implementation, a total of 3,445 cases with randomized lesion sizes, locations, and optical properties were generated and used for training with 10% randomly assigned to validation. In addition, a separate set of 400 cases, 100 each for 8-, 10-, 12- and 16-mm diameter inclusions of randomized locations and optical properties, were generated and used for testing and comparing model performance among various methods described above.

A two-step training strategy was used to train the three-part machine learning model, as described above. First, the fully connected and the convolutional autoencoder network were trained together for up to 300 epochs with starting learning rate a=0.001 and exponential decay rates P1=0.9, P2=0.999. Early stopping was enabled if validation loss did not reduce further in the past 10 epochs. Once trained, the weights of the first two parts were fixed and training of the third part (i.e., the U-Net) proceeded. The learning rate was reset to 0.001 and the network was trained for another 200 epochs, or until an early stopping criterion is met.

The one or more trained machine learning models are then stored for later use, as indicated at step 606. Storing the machine learning model(s) may include storing network parameters (e.g., weights, biases, or both), which have been computed or otherwise estimated by training the neural network(s) on the training data. Storing the trained machine learning model(s) may also include storing the particular neural network architecture(s) to be implemented. For instance, data pertaining to the layers in the neural network architecture (e.g., number of layers, type of layers, ordering of layers, connections between layers, hyperparameters for layers) may be stored.

Referring now to FIG. 7, an example of a system 700 for reconstructing enhanced images from sensor data in accordance with some embodiments of the systems and methods described in the present disclosure is shown. As shown in FIG. 7, a computing device 750 can receive one or more types of data (e.g., sensor data, structural imaging data) from data source 702. In some embodiments, computing device 750 can execute at least a portion of a machine learning-based image reconstruction system 704 to reconstruct and enhance images from data received from the data source 702.

Additionally or alternatively, in some embodiments, the computing device 750 can communicate information about data received from the data source 702 to a server 752 over a communication network 754, which can execute at least a portion of the machine learning-based image reconstruction system 704. In such embodiments, the server 752 can return information to the computing device 750 (and/or any other suitable computing device) indicative of an output of the machine learning-based image reconstruction system 704.

In some embodiments, computing device 750 and/or server 752 can be any suitable computing device or combination of devices, such as a desktop computer, a laptop computer, a smartphone, a tablet computer, a wearable computer, a server computer, a virtual machine being executed by a physical computing device, and so on. The computing device 750 and/or server 752 can also reconstruct images from the data.

In some embodiments, data source 702 can be any suitable source of data (e.g., measurement data, images reconstructed from measurement data, processed image data), such as an imaging system (e.g., a DOT imaging system, a combined DOT-DBT imaging system, etc.), another computing device (e.g., a server storing measurement data, images reconstructed from measurement data, processed image data), and so on. In some embodiments, data source 702 can be local to computing device 750. For example, data source 702 can be incorporated with computing device 750 (e.g., computing device 750 can be configured as part of a device for measuring, recording, estimating, acquiring, or otherwise collecting or storing data). As another example, data source 702 can be connected to computing device 750 by a cable, a direct wireless link, and so on. Additionally or alternatively, in some embodiments, data source 702 can be located locally and/or remotely from computing device 750, and can communicate data to computing device 750 (and/or server 752) via a communication network (e.g., communication network 754).

In some embodiments, communication network 754 can be any suitable communication network or combination of communication networks. For example, communication network 754 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some embodiments, communication network 754 can be a local area network, a wide area network, a public network (e.g., the Internet), a private or semi-private network (e.g., a corporate or university intranet), any other suitable type of network, or any suitable combination of networks. Communications links shown in FIG. 7 can each be any suitable communications link or combination of communications links, such as wired links, fiber optic links, Wi-Fi links, Bluetooth links, cellular links, and so on.

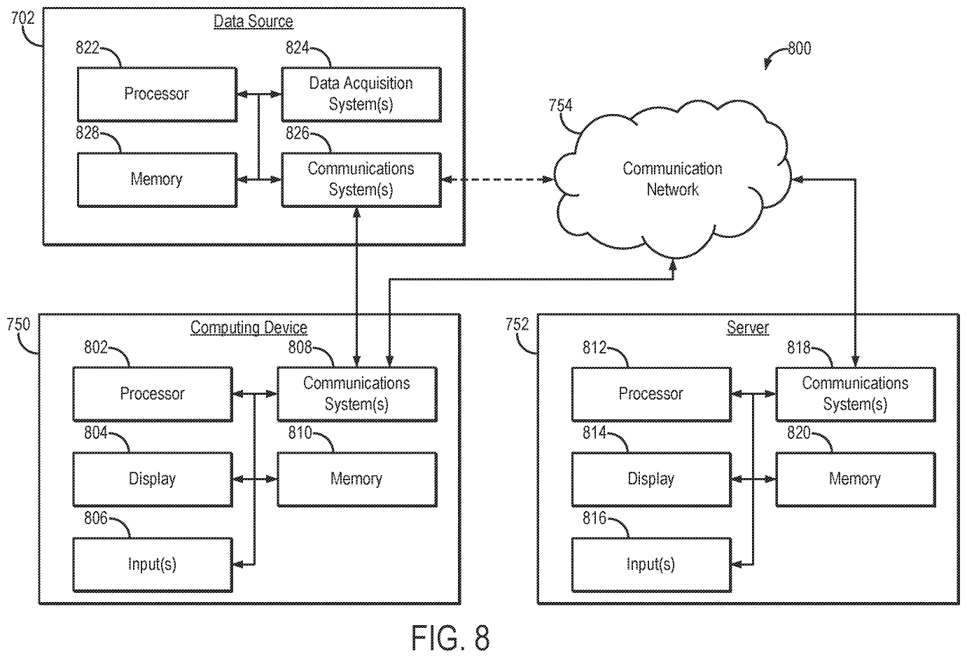

Referring now to FIG. 8, an example of hardware 800 that can be used to implement data source 702, computing device 750, and server 752 in accordance with some embodiments of the systems and methods described in the present disclosure is shown.

As shown in FIG. 8, in some embodiments, computing device 750 can include a processor 802, a display 804, one or more inputs 806, one or more communication systems 808, and/or memory 810. In some embodiments, processor 802 can be any suitable hardware processor or combination of processors, such as a central processing unit (“CPU”), a graphics processing unit (“GPU”), and so on. In some embodiments, display 804 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some embodiments, inputs 806 can include any suitable input devices and/or sensors that can be used to receive user input, such as a keyboard, a mouse, a foot pedal, a touchscreen, a microphone, and so on.

In some embodiments, communications systems 808 can include any suitable hardware, firmware, and/or software for communicating information over communication network 754 and/or any other suitable communication networks. For example, communications systems 808 can include one or more transceivers, one or more communication chips and/or chip sets, and so on. In a more particular example, communications systems 808 can include hardware, firmware, and/or software that can be used to establish a Wi-Fi connection, a Bluetooth connection, a cellular connection, an Ethernet connection, and so on.

In some embodiments, memory 810 can include any suitable storage device or devices that can be used to store instructions, values, data, or the like, that can be used, for example, by processor 802 to present content using display 804, to communicate with server 752 via communications system(s) 808, and so on. Memory 810 can include any suitable volatile memory, non-volatile memory, storage, or any suitable combination thereof. For example, memory 810 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some embodiments, memory 810 can have encoded thereon, or otherwise stored therein, a computer program for controlling operation of computing device 750. In such embodiments, processor 802 can execute at least a portion of the computer program to present content (e.g., images, user interfaces, graphics, tables), receive content from server 752, transmit information to server 752, and so on. For example, the processor 802 and the memory 810 can be configured to perform the methods described herein (e.g., the workflow shown in FIG. 2, the workflow shown in FIG. 4, the method of FIG. 5, the method of FIG. 6).

In some embodiments, server 752 can include a processor 812, a display 814, one or more inputs 816, one or more communications systems 818, and/or memory 820. In some embodiments, processor 812 can be any suitable hardware processor or combination of processors, such as a CPU, a GPU, and so on. In some embodiments, display 814 can include any suitable display devices, such as an LCD screen, LED display, OLED display, electrophoretic display, a computer monitor, a touchscreen, a television, and so on. In some embodiments, inputs 816 can include any suitable input devices and/or sensors that can be used to receive user input, such as a keyboard, a mouse, a foot pedal, a touchscreen, a microphone, and so on.

In some embodiments, communications systems 818 can include any suitable hardware, firmware, and/or software for communicating information over communication network 754 and/or any other suitable communication networks. For example, communications systems 818 can include one or more transceivers, one or more communication chips and/or chip sets, and so on. In a more particular example, communications systems 818 can include hardware, firmware, and/or software that can be used to establish a Wi-Fi connection, a Bluetooth connection, a cellular connection, an Ethernet connection, and so on.

In some embodiments, memory 820 can include any suitable storage device or devices that can be used to store instructions, values, data, or the like, that can be used, for example, by processor 812 to present content using display 814, to communicate with one or more computing devices 750, and so on. Memory 820 can include any suitable volatile memory, non-volatile memory, storage, or any suitable combination thereof. For example, memory 820 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 820 can have encoded thereon a server program for controlling operation of server 752. In such embodiments, processor 812 can execute at least a portion of the server program to transmit information and/or content (e.g., data, images, a user interface) to one or more computing devices 750, receive information and/or content from one or more computing devices 750, receive instructions from one or more devices (e.g., a personal computer, a laptop computer, a tablet computer, a smartphone), and so on.

In some embodiments, the server 752 is configured to perform the methods described in the present disclosure. For example, the processor 812 and memory 820 can be configured to perform the methods described herein (e.g., the workflow shown in FIG. 2, the workflow shown in FIG. 4, the method of FIG. 5, the method of FIG. 6).

In some embodiments, data source 702 can include a processor 822, one or more data acquisition systems 824, one or more communications systems 826, and/or memory 828. In some embodiments, processor 822 can be any suitable hardware processor or combination of processors, such as a CPU, a GPU, and so on. In some embodiments, the one or more data acquisition systems 824 are generally configured to acquire data, images, or both, and can include an imaging system such as a DOT imaging system, a combined DOT-DBT imaging system, and so on. Additionally or alternatively, in some embodiments, the one or more data acquisition systems 824 can include any suitable hardware, firmware, and/or software for coupling to and/or controlling operations of an imaging system, such as a DOT imaging system, a combined DOT-DBT imaging system, and so on. In some embodiments, one or more portions of the data acquisition system(s) 824 can be removable and/or replaceable.

Note that, although not shown, data source 702 can include any suitable inputs and/or outputs. For example, data source 702 can include input devices and/or sensors that can be used to receive user input, such as a keyboard, a mouse, a foot pedal, a touchscreen, a microphone, a trackpad, a trackball, and so on. As another example, data source 702 can include any suitable display devices, such as an LCD screen, an LED display, an OLED display, an electrophoretic display, a computer monitor, a touchscreen, a television, etc., one or more speakers, and so on.

In some embodiments, communications systems 826 can include any suitable hardware, firmware, and/or software for communicating information to computing device 750 (and, in some embodiments, over communication network 754 and/or any other suitable communication networks). For example, communications systems 826 can include one or more transceivers, one or more communication chips and/or chip sets, and so on. In a more particular example, communications systems 826 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 828 can include any suitable storage device or devices that can be used to store instructions, values, data, or the like, that can be used, for example, by processor 822 to control the one or more data acquisition systems 824, and/or receive data from the one or more data acquisition systems 824; to generate images from data; present content (e.g., data, images, a user interface) using a display; communicate with one or more computing devices 750; and so on. Memory 828 can include any suitable volatile memory, non-volatile memory, storage, or any suitable combination thereof. For example, memory 828 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 828 can have encoded thereon, or otherwise stored therein, a program for controlling operation of data source 702. In such embodiments, processor 822 can execute at least a portion of the program to generate images, transmit information and/or content (e.g., data, images, a user interface) to one or more computing devices 750, receive information and/or content from one or more computing devices 750, receive instructions from one or more devices (e.g., a personal computer, a laptop computer, a tablet computer, a smartphone, etc.), and so on.

In some embodiments, any suitable computer-readable media can be used for storing instructions for performing the functions and/or processes described herein. For example, in some embodiments, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

As used herein in the context of computer implementation, unless otherwise specified or limited, the terms “component,” “system,” “module,” “framework,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

In some implementations, devices or systems disclosed herein can be utilized or installed using methods embodying aspects of the disclosure. Correspondingly, description herein of particular features, capabilities, or intended purposes of a device or system is generally intended to inherently include disclosure of a method of using such features for the intended purposes, a method of implementing such capabilities, and a method of installing disclosed (or otherwise known) components to support these purposes or capabilities. Similarly, unless otherwise indicated or limited, discussion herein of any method of manufacturing or using a particular device or system, including installing the device or system, is intended to inherently include disclosure, as embodiments of the disclosure, of the utilized features and implemented capabilities of such device or system.

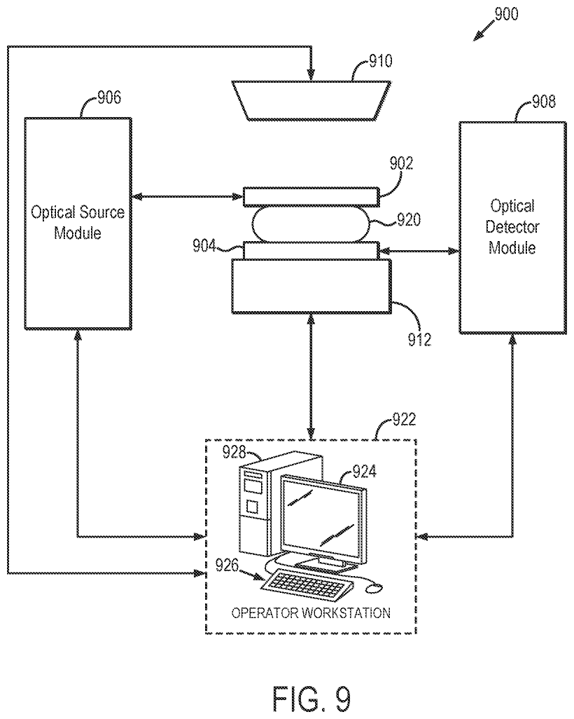

As described above, in some examples a multimodal breast imaging system combining DOT with DBT can be used to acquire sensor data and structural imaging data. An example tomographic optical breast imager (“TOBI”) is shown in FIG. 9. Advantageously, the TOBI system 900 can acquire spatially co-registered optical images and breast tomosynthesis images. The TOBI system 900 generally includes an optical source plate 902 and an optical detector plate 904 arranged in a tomographic configuration. The optical source plate 902 and optical detector plate 904 can act as compression plate for the breast tomosynthesis imaging components of the TOBI system 900. An optical source module 906 can include both continuous-wave (“CW”) and radio-frequency (“RF”) modulated lasers at multiple wavelengths, such as about 680 and about 830 nm, and can be capable of imaging tissue scattering in addition to total hemoglobin concentration (“[HbT]”) and tissue oxygenation (“SO₂”), and may also be capable of quantifying composite values by combining measurable optical properties of tissue. An optical detector modulate 908 contains data acquisition components for receiving optical signals from the optical detector plate 904 and storing the optical signals as sensor data.

The TOBI system 900 also includes an x-ray source 910 opposite an x-ray detector 912. The x-ray source 910 may be arranged on the same side of the TOBI system 900 as the optical source plate 902, and the x-ray detector 912 may be arranged on the same side of the TOBI system 900 as the optical detector plate 904.

The x-ray source 910 projects an x-ray beam, which may be a fan-beam or cone-beam of x-rays, towards the x-ray detector 912 on the opposite side of the TOBI system 900. The x-ray detector 912 may include an x-ray detector array composed of a number of x-ray detector elements. Examples of x-ray detectors that may be included in the x-ray detector 912 include flat panel detectors. Together, the x-ray detector elements in the x-ray detector 912 sense the projected x-rays that pass through a subject 920 (e.g., a subject's breast) arranged between the optical source plate 902 and optical detector plate 904 of the TOBI system 900. Each x-ray detector element produces an electrical signal that may represent the intensity of an impinging x-ray beam and, thus, the attenuation of the x-ray beam as it passes through the subject 920.

The TOBI system 900 also includes an operator workstation 922, which typically includes a display 924; one or more input devices 926, such as a foot pedal, keyboard, and/or mouse; and a computer processor 928. The computer processor 928 may include a commercially available programmable machine running a commercially available operating system. The operator workstation 922 provides the operator interface that enables imaging control parameters to be entered into the TOBI system 900. The operator workstation 922 or another connected computer system may sample data from the x-ray detector 912 and/or the optical detector module 908.

The present disclosure has described one or more preferred embodiments, and it should be appreciated that many equivalents, alternatives, variations, and modifications, aside from those expressly stated, are possible and within the scope of the invention.

1. A method for reconstructing an image from sensor data, comprising:
receiving, by a computer system, sensor data from an imaging system;
accessing a machine learning model with the computer system, wherein the machine learning model comprises a first subnetwork that receives sensor data as an input and generates an intermediate image as a first output, and a second subnetwork that receives the first output from the first subnetwork and generates an enhanced image as a second output;
inputting the sensor data to the machine learning model using the computer system, generating an enhanced image as an output; and
presenting the enhanced image to a user with the computer system.

2. The method of claim 1, wherein the first subnetwork comprises a first component and a second component;
wherein the first component converts the sensor data from a sensor domain to an image domain, generating image-domain data as an output; and
wherein the second component extracts images features from the image-domain data.

3. The method of claim 2, wherein the first component comprises an artificial neural network comprising at least two fully connected layers.

4. The method of claim 2, wherein the second component comprises an artificial neural network comprising a convolutional autoencoder.

5. The method of claim 1, wherein the second subnetwork comprises a convolutional neural network.

6. The method of claim 1, wherein the sensor data comprise functional imaging data.

7. The method of claim 6, wherein the functional imaging data comprise optical imaging data.

8. The method of claim 7, wherein the optical imaging data comprise diffuse optical tomography (DOT) data.

9. The method of claim 8, wherein the DOT data comprise three-dimensional (3D) DOT data.

10. The method of claim 1, further comprising accessing structural imaging data with the computer system and inputting the structural imaging data as an additional input to the machine learning model.

11. The method of claim 10, wherein the structural imaging data are input to the second subnetwork of the machine learning model.

12. The method of claim 10, wherein the first subnetwork comprises a first component and a second component;
wherein the first component converts the sensor data from a sensor domain to an image domain, generating image-domain data as an output;
wherein the second component extracts images features from the image-domain data; and
wherein the structural imaging data are input to the second component.

13. The method of claim 10, wherein the structural imaging data comprise x-ray imaging data.

14. The method of claim 13, wherein the sensor data comprise diffuse optical tomography (DOT) data.

15. A method for training a machine learning model for multimodal image reconstruction, the method comprising:
(a) accessing first imaging data with a computer system, wherein the first imaging data were acquired from a group of subjects;
(b) accessing second imaging data with the computer system, wherein the second imaging data were acquired from the group of subjects and have a higher spatial resolution than the first imaging data;
(c) assembling the first imaging data into a first training dataset and the second imaging data into a second training data set;
(d) accessing a machine learning model with the computer system, wherein the machine learning model comprises a first subnetwork that receives first imaging data as an input and generates an intermediate image as a first output, and a second subnetwork that receives the first output from the first subnetwork and generates an enhanced image as a second output;
(e) training the first subnetwork on the first training dataset;
(f) training the second subnetwork on the second training data set; and
(g) storing the trained first subnetwork and the trained second subnetwork as a trained machine learning model.

16. The method of claim 15, wherein assembling the first training dataset includes generating noise-added imaging data from the first imaging data with the computer system and storing the noise-added imaging data as the first training dataset.

17. The method of claim 16, wherein the noise-added imaging data are generated by inputting the first imaging data to a generative adversarial network (GAN) to add realistic noise to the first imaging data.

18. The method of claim 15, wherein the first subnetwork is trained on the first training dataset using a prior-weighted loss function that penalizes more heavily on inaccuracies within a region-of-interest (ROI) in the first training dataset.

19. The method of claim 18, wherein the prior-weighted loss function receives as an input prior knowledge of a location and size of abnormalities in the first training dataset.

20. The method of claim 15, wherein the first subnetwork comprises a first component and a second component;
wherein the first component converts the first imaging data from a sensor domain to an image domain, generating image-domain data as an output; and
wherein the second component extracts images features from the image-domain data.

21. The method of claim 20, wherein the first component comprises an artificial neural network comprising at least two fully connected layers.

22. The method of claim 20, wherein the second component comprises an artificial neural network comprising a convolutional autoencoder.

23. The method of claim 15, wherein the second subnetwork comprises a convolutional neural network.

24. The method of claim 15, wherein the first imaging data are acquired with a first imaging modality and the second imaging data are acquired with a second imaging modality that is different from the first imaging modality.

25. The method of claim 24, wherein the first imaging modality is a functional imaging modality and the second imaging modality is a structural imaging modality.

26. The method of claim 25, wherein the first imaging modality comprises diffuse optical tomography and the second imaging modality comprises x-ray imaging.
